(19) United States
(12) Patent Application Publication
(10) Pub. No.: US 2004/0121267 A1
(43) Pub. Date: Jun. 24, 2004

(54) Method of fabricating lead-free solder bumps

(75) Inventor: Se-Young Jang, Suwon city (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon City (KR)

(21) Appl. No.: 10/706,033

(22) Filed: Nov. 13, 2003

(30) Foreign Application Priority Data
Mar. 12, 2003 (KR) 2003-15503
Dec. 23, 2002 (KR) 2002-82446

(51) Int. Cl. G03F 7/00

(52) U.S. Cl. 430/315; 430/311

(57) ABSTRACT

A method of fabricating lead-free solder bumps, including providing a wafer having a protective layer with an open electrode pad; forming an UBM (under bump metallization) layer on the wafer; lithographing a photoresist on the UBM layer, excluding a portion of the UBM layer corresponding to the electrode pad; forming a copper layer on the portion of the UBM layer corresponding to the electrode pad; plating solder on the copper layer; removing the photoresist; and etching the UBM layer using the solder as a mask, and reflowing the solder and fabricating solder bumps.

### CROSS-REFERENCE TO RELATED APPLICATIONS

This application claims the benefit of Korean Patent Application Nos. 2003-15503, filed Mar. 12, 2003, and 2002-82446, filed Dec. 23, 2002, in the Korean Intellectual Property Office, the disclosures of which are incorporated herein by reference.

### BACKGROUND OF THE INVENTION

1. Field of the Invention

The present invention relates to a method of fabricating solder bumps, which are terminals of a semiconductor, using a flip-chip interconnection, and, more particularly, to a method of fabricating lead-free solder bumps easily, reducing fabricating cost, and allowing easy control of electroplating control.

2. Description of the Related Art

A conventional wire bonding method electrically connects electrode pads of a semiconductor wafer to leads of a lead frame with gold wires. In contrast, a flip-chip method connects the semiconductor wafer to terminals of a PCB (printed circuit board), in which the semiconductor wafer is embedded, with bumps formed on the semiconductor wafer.

Conventionally, solder comprising lead (Pb) and tin (Sn) as principal elements has been used so that the bumps can be formed on the electrode pads of the semiconductor wafer.

Because of increasing environmental problems, regulations have been proposed to eliminate the use of lead in electronic products, starting in Europe and Japan, and recently spreading worldwide. In the EU, a car recycling law regulates lead-based solder. Also, in Japan, according to the Waste and Cleanup Law (Waste Treatment and Public Cleanup Law) and the Home Appliances Recycling Law, removing lead from home appliances is obligatory. Accordingly, a process of fabricating electronic products containing lead needs to be converted to a lead-free process, and the solder bumps on the semiconductor wafer need to be formed by using lead-free solder.

Thus, solders of Pb—Ag—Cu ternary alloy, or Sn—Ag or Sn—Cu binary alloys have been substituted for the Pb—Sn solder conventionally used.

However, because the fusing point of the lead-free solders described above changes greatly according to a change in the alloy composition ratio, the alloy composition ratio of the lead-free solders usable at a 270° C. reflow temperature has a narrow alloy composition region between about 3% through about 7%. Also, because copper and silver added in very small amounts (about 1% to about 2%) increase the fusing point of the alloys by 10° C. or more and may cause a connection failure, the alloy composition ratio must be accurately set. Further, conventionally, a complexing agent has been used because silver and copper having a high reduction potential as compared to tin, are preferentially electroplated. However, the fabricating cost is high because of the high price of the complexing agent.

### SUMMARY OF THE INVENTION

It is an aspect of the present invention to provide a method of easily fabricating binary lead-free solder bumps with only unitary tin plating, or tin-silver-copper ternary lead-free solder bumps with only binary tin-silver plating, by diffusing copper into solders when reflowing the solders by layering the copper, which is one of the elements of the lead-free solders, on an UBM (under bump metallization) layer provided in lower parts of the solder bumps.

Additional aspects and/or advantages of the invention will be set forth in part in the description that follows and, in part, will be obvious from the description, or may be learned by practice of the invention.

To achieve the above and/or other aspects of the present invention, there is provided a method of fabricating lead-free solder bumps, including providing a wafer having a protective layer with an open electrode pad; forming an UBM (under bump metallization) layer on the wafer; lithographing a photoresist on the UBM layer, excluding a portion of the UBM layer corresponding to the electrode pad; forming a copper layer on the portion of the UBM layer corresponding to the electrode pad; plating solder on the copper layer; removing the photoresist; and etching the UBM layer using the solder as a mask, and reflowing the solder and fabricating solder bumps.

In one instance, the solder comprises tin.

In another instance, the solder further comprises silver.

The reflowing is performed for about 1 minute to about 20 minutes at a temperature of about 230° to about 270° C.

The copper layer has a thickness ranging from about 5 μm to about 20 μm.

The UBM layer includes a first layer applied to the wafer, having one of titanium (Ti), tungsten (W), chrome (Cr), and titanium/tungsten (TiW), and a second layer applied to the first layer, having one of copper (Cu), nickel (Ni), a nickel/vanadium (Ni—V) alloy, and a copper/nickel (Cu—Ni) alloy.

To achieve the above and/or other aspects according to the present invention, there is provided a lead-free solder bump of a semiconductor wafer, including a semiconductor wafer; an electrode pad formed on the semiconductor wafer; a protective layer formed on the semiconductor wafer around the electrode pad; an under bump metallization layer (UBM) formed on the electrode pad and the protective layer; a photoresist formed on the UBM layer, excluding a portion of the UBM layer corresponding to the electrode pad; a copper layer formed on the UBM layer corresponding to the electrode pad; and solder plated on the copper layer, wherein the photoresist is removed, the UBM layer is etched using the solder as a mask, and the solder is reflowed to form a solder bump.

These, together with other aspects and/or advantages that will be subsequently apparent, reside in the details of construction and operation as more fully hereinafter described and claimed, reference being had to the accompanying drawings forming a part thereof, wherein like numerals refer to like parts throughout.

### BRIEF DESCRIPTION OF THE DRAWINGS

These and/or other aspects and advantages of the invention will become apparent and more readily appreciated from the following description of the preferred embodiments, taken in conjunction with the accompanying drawings, of which:

FIGS. 1A through 1F are sectional views illustrating a process of fabricating lead-free solder bumps according to an embodiment of the present invention; and

FIGS. 2A and 2B are sectional views illustrating diffusion of copper into the lead-free solders during reflow of the lead-free solders according to the present invention.

### DETAILED DESCRIPTION OF THE PREFERRED EMBODIMENT

Hereinafter, an embodiment of the present invention will be described in detail with reference to the attached drawings, wherein the like reference numerals refer to the like elements throughout. The present invention may, however, be embodied in many different forms and should not be construed as being limited to the embodiment set forth herein. Rather, this embodiment is provided so that the present disclosure will be thorough and complete, and will fully convey the concept of the invention to those skilled in the art.

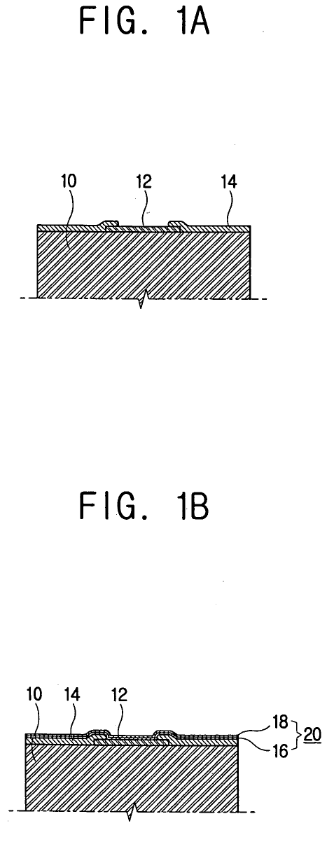

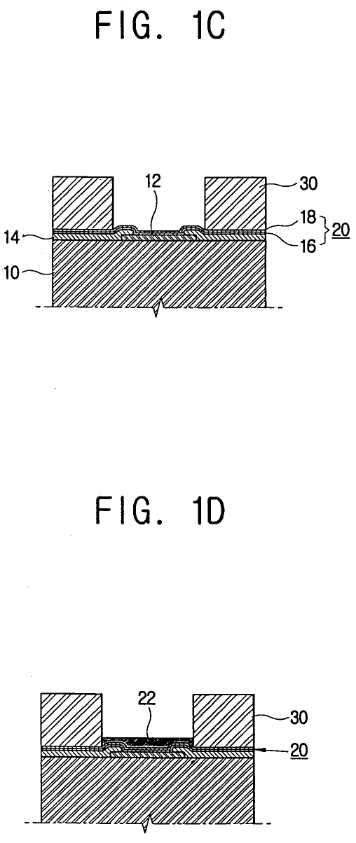

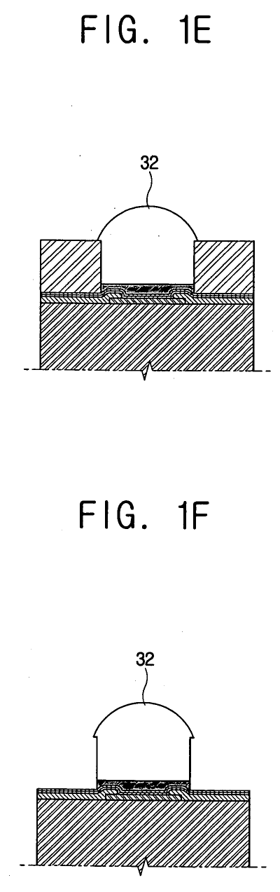

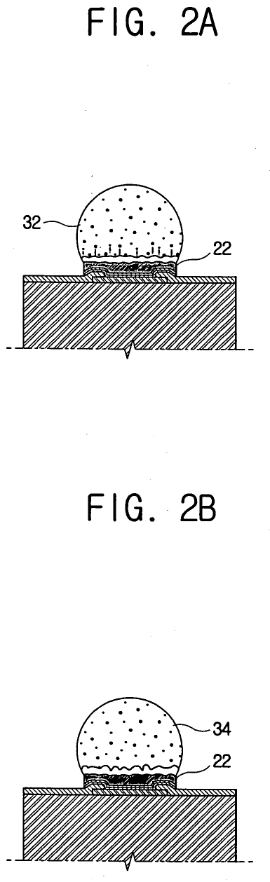

FIG. 1A is a sectional view of a semiconductor wafer 10 having a protective layer 14 with an open electrode pad 12, and FIG. 1B is a sectional view illustrating an UBM (under bump metallization) layer 20 formed on the semiconductor wafer 10. The UBM layer 20 protects against diffusion between the electrode pad 12 and solder when the solder is reflowed after being electroplated on the electrode pad 12, which is made of a metal such as aluminum. The UBM layer 20 also provides an electric path connecting all the areas of the semiconductor wafer 10, and increases interface cohesion between the electrode pad 12 and a solder bump 34 (refer to FIG. 2B) in flip-chip interconnection. A first layer 16 of the UBM layer 20, which is applied to the semiconductor wafer 10, comprises one of titanium (Ti), tungsten (W), chrome (Cr), and titanium/tungsten (TiW), and a second layer 18, which is applied to the first layer 16, comprises one of copper (Cu), nickel (Ni), a nickel/vanadium (Ni—V) alloy, and a copper/nickel (Cu—Ni) alloy. The UBM layer 20 is formed sequentially by sputtering, and requires good cohesion with the semiconductor wafer 10 and must be undamaged during the continuous formation processes.

As shown in FIG. 1C, a photoresist 30 is lithographied on the UBM layer 20, excluding a portion corresponding to the electrode pad 12. Further, as shown in FIG. 1D, a copper layer 22 is formed on the portion of the UBM 20 corresponding the electrode pad 12. Then, solder 32 is electroplated on the copper layer 22 (refer to FIG. 1E), directly contacting the copper layer 22. The solder 32 comprises tin as a principal element. At this point, the copper layer 22 has a thickness in the range of about 5 μm to about 20 μm.

Subsequently, as shown in FIG. 1F, the photoresist 30 is removed, and the UBM layer 20 is etched (not shown) using the solder 32 as a mask. Finally, the solder 32 is reflowed. FIG. 2A illustrates that the copper in the copper layer 22 diffuses to the solder 32 during the reflow process, and FIG. 2B illustrates formation of a tin-copper binary solder bump 34 by the diffusion of the copper to the solder 32.

The reflow is processed in an organic solvent having a temperature ranging from about 230° C. to about 270° C. When the solder 32 consists of only tin, if the reflow temperature of the solder 32 is greater than about 232° C., that is, greater than the fusing point of tin, the copper in the copper layer 22, which is layered on the UBM layer 20, diffuses into the tin solder 32, and, simultaneously, the tin in the solder 32 diffuses into the copper layer 22 to form a copper-tin metal compound layer at the interface of the solder 32 and the copper layer 22, which increases electrical conductivity. A predetermined amount of copper remains in the solder bump 34 after the reflow.

The solder 32 may also comprise silver, with tin being the principal element, which forms a tin-silver binary lead-free alloy, and the composition ratio thereof can be easily controlled as compared to a tin-silver-copper ternary lead-free alloy. Because the diffusion amount of the copper to the solder 32 is controlled by adjustment of the temperature and the amount of time for the reflow according to the present invention, a ternary bump fabrication process having a high fabrication cost and difficult quality control can be replaced with a binary bump fabrication process.

Table 1 provides results of the analysis of the content of copper in an upper part of the solder bump 34 using energy dispersive X-ray spectroscopy (EDX) after a Sn/3.5Ag alloy is electroplated on various structures of the BM layer 20 and the reflow processes are performed under various temperatures and amounts of time. As shown in Table 1, after the reflow processes, the content of copper in the solder bump 34 ranges from about 1.5% to about 3% depending on the heat treatment conditions. These results show that copper does not need to be separately added during the electroplating process to add a very small amount (about 1%) of copper when fabricating a lead-free solder bump having a small size (e.g., less than about 150 μm).

TABLE 1
Content of copper in solder bumps, after reflowing Sn/3.5Ag
solder bumps on an UBM having different layers

| | | | 1000 hours heat |
|---|---|---|---|
| | 1 minute | 20 minutes | treatment after 1 |
| Kinds of UBM | reflow | reflow | minute reflow |
| TiW/Cu/ | 2.2 +/− 0.9 | 2.6 +/− 0.9 | 1.5 +/− 0.2 |
| electroplated Cu | | | |
| Cr/Cr—Cu/Cu | 1.2 +/− 0.1 | 2.9 +/− 0.5 | 1.7 +/− 0.6 |
| NiV/Cu | 1.7 +/− 0.1 | 2.3 +/− 0.3 | 1.5 +/− 0.4 |

In a general reflow oven under a nitrogen environment limiting oxygen content, solder flux is spread and a solder bump 34 can be fused. The reflow of the solder bump 34 can be performed before or after etching the UBM layer 20.

With the above configuration, according to the present invention, without fabricating an electroplating solution for binary and ternary solder alloys, the composition ratio of the copper contained in the solder bump 34 can be easily controlled by the diffusion of the copper on the UBM layer 20 into the solder 32.

As described above, according to the present invention, copper is diffused into solder during reflow of the solder by layering copper on an UBM, and binary or ternary lead-free solder bumps can be easily fabricated by using only unitary or binary tin plating accordingly.

Thus, lead-free solder bumps having a low fabrication cost and an easy plating control can be fabricated.

Although a preferred embodiment of the present invention has been shown and described, it will be appreciated by those skilled in the art that changes may be made in this embodiment without departing from the principles and spirit of the invention, the scope of which is defined in the claims and their equivalents.

What is claimed is:

1. A method of fabricating lead-free solder bumps, comprising:
providing a wafer having a protective layer with an open electrode pad;
forming an UBM (under bump metallization) layer on the wafer;
lithographing a photoresist on the UBM layer, excluding a portion of the UBM layer corresponding to the electrode pad;
forming a copper layer on the portion of the UBM layer corresponding to the electrode pad;
plating solder on the copper layer;
removing the photoresist; and
etching the UBM layer using the solder as a mask, and reflowing the solder and fabricating the solder bumps.

2. The method of fabricating lead-free solder bumps according to claim 1, wherein the solder comprises tin.

3. The method of fabricating lead-free solder bumps according to claim 2, wherein the solder further comprises silver.

4. The method of fabricating lead-free solder bumps according to claim 1, wherein the reflowing is performed for about 1 minute to about 20 minutes at a temperature of about 230° to about 270° C.

5. The method of fabricating lead-free solder bumps according to claim 1, wherein the copper layer has a thickness ranging from about 5 μm to about 20 μm.

6. The method of fabricating lead-free solder bumps according to claim 1, wherein the UBM layer comprises a first layer applied to the wafer, having one of titanium (Ti), tungsten (W), chrome (Cr), and titanium/tungsten (TiW), and a second layer applied to the first layer, having one of copper (Cu), nickel (Ni), a nickel/vanadium (Ni—V) alloy, and a copper/nickel (Cu—Ni) alloy.

7. A lead-free solder bump of a semiconductor wafer, comprising:
a semiconductor wafer;
an electrode pad formed on the semiconductor wafer;
a protective layer formed on the semiconductor wafer around the electrode pad;
an under bump metallization layer (UBM) formed on the electrode pad and the protective layer;
a copper layer formed on the UBM layer corresponding to the electrode pad; and
solder plated on the copper layer,
wherein UBM layer was etched using the solder as a mask, and the solder was reflowed to form a solder bump.

8. The solder bump of claim 7, wherein the UBM layer prevents diffusion between the electrode pad and the solder when the solder was reflowed, provides an electric path connecting all areas of the semiconductor wafer, and increases interface cohesion between the electrode pad and the solder bump.

9. The solder bump of claim 7, wherein the solder bump is a tin-copper binary solder bump formed by copper in the copper layer diffusing into the solder when the solder is reflowed.

10. The solder bump of claim 7, wherein the solder comprises tin.

11. The solder bump of claim 10, further comprising a copper-tin metal compound layer at an interface of the solder and the copper layer, formed by, when a temperature of the reflow of the solder is greater than a fusing point of the tin, a predetermined amount of copper in the copper layer diffusing into the solder and, simultaneously, the tin of the solder diffusing into the copper layer.

12. The solder bump of claim 10, wherein the solder further comprises silver, with the tin being the principal element in the solder, forming a tin-silver binary lead-free alloy.

13. The solder bump of claim 9, wherein a diffusion amount of the copper to the solder is controlled by adjusting a temperature and an amount of time of the reflow of the solder.

14. The method of fabricating lead-free solder bumps according to claim 1, wherein said reflowing the solder is performed before said etching the UBM layer.

15. The method of fabricating lead-free solder bumps according to claim 1, wherein said reflowing the solder is performed after said etching the UBM layer.

16. A method of fabricating lead-free solder bumps on a wafer having an electrode pad, comprising:
forming an UBM (under bump metallization) layer on the wafer;
forming a copper layer on the portion of the UBM layer corresponding to the electrode pad and plating solder on the copper layer; and
reflowing the solder to form the solder bumps.

17. The method of fabricating lead-free solder bumps according to claim 16, further comprising:
lithographing a photoresist on the UBM layer, excluding a portion of the UBM layer corresponding to the electrode pad, after said forming an UBM layer on the wafer;
removing the photoresist after said plating solder on the copper layer; and
etching the UBM layer using the solder as a mask after said removing the photoresist.

18. The method of fabricating lead-free solder bumps according to claim 16, further comprising:
lithographing a photoresist on the UBM layer, excluding a portion of the UBM layer corresponding to the electrode pad, after said forming an UBM layer on the wafer;
removing the photoresist after said plating solder on the copper layer; and
etching the UBM layer using the solder as a mask after said reflowing the solder to form the solder bumps.
